(19) United States
(12) Patent Application Publication
(10) Pub. No.: US 2015/0170967 A1
(43) Pub. Date: Jun. 18, 2015

(54) Methods for Substrate and Device Fabrications

(71) Applicant: Michael Xiaoxuan Yang, Palo Alto, CA (US)

(72) Inventor: Michael Xiaoxuan Yang, Palo Alto, CA (US)

(21) Appl. No.: 14/104,601

(22) Filed: Dec. 12, 2013

(51) Int. Cl. H01L 21/78; H01L 21/461

(52) U.S. Cl. CPC H01L 21/78; H01L 21/461

(57) ABSTRACT

The present invention relates to methods in fabrication of electronics and optoelectronics devices. Devices are first fabricated on the substrate, followed by a substrate thinning process with a laser irradiation on the substrate sidewall.

This invention is further directed to methods of separating a substrate into two pieces with a laser irradiation on substrate sidewall. In one embodiment, the method involves a laser anneal of the materials, accompanied by forces applied from front and back surfaces to separate the substrate. In yet another embodiment, the method consists of both laser ablation and laser anneal process steps.

### CROSS REFERENCE TO RELATED APPLICATION

The present invention relates to prior patent application Ser. No. 13/694,525 and Ser. No. 13/694,526, filed Dec. 8, 2012, with priority dated Aug. 23, 2012.

### FIELD OF THE INVENTION

The present invention is directed to fabrication of electronics and optoelectronics devices. The methods also relate to substrate preparation and materials processing by laser irradiations.

### BACKGROUND OF THE INVENTION

The present invention is directed to fabrication of electronics and optoelectronics devices. The methods are particularly applicable to device fabrication on thin substrates, e.g. substrates of less than 200-500 microns in thickness.

Electronics and optoelectronics devices are fabricated on semi-conducting or insulating substrates. For instance, silicon wafers are substrates for semiconductor integrated circuit (IC) devices and silicon solar cells. Monocrystalline silicon wafers are generally obtained by a wiresaw slicing of silicon ingots. A cut of cylindrical silicon ingots results in round wafers which are common for fabrication of general IC and microelectromechanical systems (MEMS) devices. In crystalline silicon solar cell production, however, silicon blocks are first prepared from the cylindrical ingots, before being cut into square or substantially square wafers.

In semiconductor IC industry, wafers cut from silicon ingots in wiresaw tools go through additional grinding/polishing/cleaning to remove surface damage, roughness and particles. In cost-driven solar cell production, silicon wafers cut from ingots are used as-is without expensive grinding/polishing steps.

A cutting of hard materials such as silicon by wire saws is associated with significant consumable cost (cutting wires and slurries) and a considerable kerf loss, i.e. the amount of materials removed by cutting wires. Despite of the continuous improvements in wiresaw equipment, process and materials, it is challenging to produce silicon wafers of less than 100 microns thickness with a kerf loss of less than 100 microns. In order to reduce solar cell manufacturing cost, silicon solar wafers in mass production today are at a thickness of 150-200 microns, approaching the limit of minimum substrate thickness in a silicon wiresaw cutting tool. Yet silicon substrate still accounts for >50% of the total solar cell manufacturing cost.

In comparison with silicon substrates in solar cell production, silicon wafers in semiconductor IC industry are much more expensive, yet remains a very small fraction of the total device fabrication cost. Per unit area, a prime silicon substrate for IC fabrication can be over two orders of magnitude more expensive than single crystalline silicon substrates in solar industry. On the other hand, silicon substrate cost may account for less than five percent of the overall IC device fabrication cost. As substrate cost is not a predominant factor, silicon wafers adopted in IC production are significantly thicker than those in solar industry, as thicker wafers are much easier to handle through the tedious IC device fabrication flow.

Multiple IC devices are fabricated on a single silicon wafer, known as dies. In order to increase manufacturing equipment throughput thus to reduce overall IC manufacturing cost, silicon wafers for semiconductor IC industry are getting larger. 300 mm diameter silicon wafers are in production today, and next generation 450 mm silicon wafers are expected to produce >2× of dies per wafer. An increase in silicon wafer size is accompanied by an increase in wafer thickness. 300 mm diameter wafers have a standard thickness of ˜775 microns, and 450 mm wafers are expected to be ˜900 microns in thickness.

After completion of the manufacturing flow, the wafers are thinned down before the wafers are cut along x- and y-directions to isolate individual dies. A reduction in die thickness can result in a compact final packaging, which is desirable in consumer electronics applications. Thin dies can also be stacked up for additional functionalities. Nowadays it is not unusual to have a final die thickness of less than 100 microns. It is the current practice to reduce silicon wafer thickness by grinding/polishing from substrate backside. The cost of silicon grinding increases with the required substrate removal thickness.

The common substrate for light-emitting iodide (LED) device fabrication is sapphire. Analogous to silicon wafer fabrication, sapphire wafers are prepared from wiresaw cutting of single crystal sapphire boules, a.k.a. sapphire cores. Most of the LED productions are carried out on 2-4 inch (50-100 millimeter) diameter sapphire wafers today, with 6 inch (150 millimeter) diameter sapphire wafers already available for development and pilot production. Sapphire is a very expensive material, thus it is attractive to reduce sapphire wafer thickness for a lower cost. However, the starting sapphire wafer thickness can be constrained by some LED fabrication processes today. A key step in LED fabrication is Metalorganic Chemical Vapor Deposition (MOCVD), in which epitaxial thin films of III/V materials are deposited on front side of the substrate at a high temperature. A uniform wafer temperature in the MOCVD process is critical to a good film composition control en route to a good LED emission light wavelength uniformity. Unfortunately, a film stress buildup during the MOCVD process can cause a wafer bow, and post a significant challenge to the wafer temperature uniformity control. In order to alleviate the issue, it is common to adopt a thick starting sapphire substrate. A relatively thick substrate can reduce the wafer bow, thus help to achieve a uniform wafer temperature during the MOCVD process. Currently two inch diameter sapphire wafers are >400 microns in thickness.

While it can be beneficial to start with a thick sapphire substrate in the LED fabrication flow, a thick sapphire substrate in the final LED device package can adversely impact LED light transmission efficiency. It is thus a common practice to reduce sapphire substrate thickness after completion of LED fabrication processes. Similar to silicon wafer thinning in IC fabrication, the sapphire wafer thinning after LED device fabrication is currently carried out through a grinding/polishing process.

Alternatively, LED devices can be detached entirely from the substrate (e.g. sapphire, silicon) and be transferred to a reflective and thermally conductive carrier, in a so-called laser lift-off process. The laser lift-off process will be discussed in more details below.

The common substrates in flat panel display (FPD) production are borosilicate glass (BSG) and its variants, e.g. alkaline earth boro-aluminosilicate glass. Display glass substrates can withstand a high temperature of >600-700 C, suitable for high-performance thin film transistor (TFT) fabrications.

Display glass substrates can be manufactured in a low cost float glass process. In BSG glass production, for instance, boric acid/silicon oxide frits are melted before flowing out on top of a tin bath, followed by a sequence of cooling stages. Large size, amorphous glass substrates with smooth surfaces and a uniform thickness can be prepared.

Glass substrate size in FPD industry increases in so-called generations (Gen). Gen 10 glass, the largest of today, is 2,880×3,130 mm in size. It allows for an efficient production of various final panel sizes and offers superior economies of scale in display manufacturing.

While the glass substrate in FPD industry gets larger, it is also getting thinner. The reduction in FPD glass substrate thickness is primarily driven by fast-growing consumer electronics applications (e.g. smart phones, tablets and ultrathin televisions). The display module in smart phones/tablets can comprise of a stack of display glasses/devices (backplane, frontplane/touchscreen, cover glass), and accounts for approximately 30% of overall device thickness today. As a result, a thinner display glass substrate is critical to a slimmer package in new generation smart phones and tablets. Nowadays Gen 8 glass substrate thickness has been reduced to ˜0.5 mm, while Gen 5 glass substrate thickness can be as thin as ˜0.3 mm. As its thickness approaching 200 microns or less, the glass substrate is also getting flexible, with additional applications in emerging flexible electronics/displays.

Thinner/larger glass sheets have a reduced mechanical strength, and are more difficult to handle in current display manufacturing lines. An alternative approach is to adopt a roll-to-roll manufacturing process with ultrathin flexible glass substrates. Glass manufacturers have developed <100 micron thick glass substrates and have been able to produce the flexible substrate in rolls. However, the thin glass substrates can have some constraints in key materials properties (e.g. thermal stability at high temperature), thus are not fully compatible with existing thin film transistor (TFT) display fabrication process. The ultrathin substrates can also be prone to crack propagation from edge. Arguably the most significant hurdle in adoption of the continuous flexible glass substrates in display fabrication is a lack of production-worthy roll-to-roll manufacturing tools. While low-cost roll-to-roll manufacturing is the production method of record in other industries, it is a paradigm shift from current display industry baseline which handles discrete large sheet glass substrates. A long-term commitment and significant capital investments are required, before a complete suite of sophisticated yet reliable roll-to-roll display fabrication equipments can be developed with product qualities and production yields competitive to established and ever improving flat panel display manufacturing lines with large size glass sheets.

Considering the challenges of the alternative approach, it is desirable to leverage existing manufacturing lines with large size glass sheets, while circumventing handling issues with ultrathin substrates. It is conceivable to start with regular thickness glass substrates, and reduce the glass substrate thickness after completion of display fabrication. It is analogous to the existing silicon and sapphire substrate thinning processes in IC and LED production, as described above. However, there is no existing production-worthy glass thinning solution which can meet requirements of both performance and cost in display industry.

The present invention is directed to a novel technology to reduce substrate thickness after device fabrication. It is applicable to device fabrications on different substrate materials, including glass substrate in display industry. The proposed methods for substrate thinning involve a laser irradiation, and different lasers can be selected for different substrate materials in different applications.

Every laser has an active media for coherent light generation. The most common active media include gases in gas lasers, semiconductor materials in semiconductor lasers, and rare-earth element doped crystals in solid state lasers. Other laser types include chemical lasers, dye lasers, metal vapor lasers, etc.

In a gas laser, an electrical circuit is discharged through a gas to produce a coherent light. For example, CO₂ lasers can emit hundreds of kilowatts at a wavelength of ˜10 microns, and are often used in industrial applications such as cutting and welding. Excimer lasers are another subgroup of gas lasers which are powered by a chemical reaction involving an excited dimer, or excimer. Common ultraviolet (UV) excimer lasers include F₂ laser (emitting at 157 nm), ArF laser (193 nm), KrCl laser (222 nm), KrF laser (248 nm), XeCl laser (308 nm), and XeF laser (351 nm).

Semiconductor lasers are commonly known as laser diodes. The active medium in laser diodes is a semiconductor material with a p-n junction. The emitting wavelength of laser diodes can range from ˜0.4 to 20 microns, with a wide range of applications including telecommunications, holography, printing, and machining/welding. Laser diodes can also serve as pump sources for other lasers, including diode pumped solid state (DPSS) lasers.

In solid state lasers, a crystalline or glass rod is “doped” with ions for the required energy states in coherent light generation. Yttrium aluminum garnet (Nd:YAG), yttrium lithium fluoride (Nd:YLF) and yttrium orthovanadate (Nd:YVO₄) lasers can produce powerful pulses at 1064 nm. The laser intensity can be amplified through an optical fiber. The so called fiber lasers can deliver multi-kilowatt laser powers with an excellent electricity to laser power conversion efficiency, and have increasing industrial applications in cutting, welding and marking of metals and other materials. The family of diode pumped solid state (DPSS) lasers also comprise of frequency-doubled 532 nm (green), frequency-tripled 355 nm (UV) and frequency-quadrupled 266 nm (UV) lasers.

There are a number of existing laser applications in electronics device fabrications. The first group of applications are laser dicing/patterning/scribing. A conventional laser dicing/patterning/scribing process involves a direct materials ablation. In a direct laser ablation process, materials are opague to the laser irradiation, and a focused laser beam heats up the materials to tens of thousands degrees, well above the materials melting and vaporization temperatures. Materials are released to the gas phase, leaving behind an imprint (e.g., a crater or groove) on the materials surface. Applications of laser ablation processes in electronics device fabrication include patterning of IC silicon wafers (e.g. via drilling in 3-D packaging) and scribing of solar cells (e.g. wafer edge isolation of silicon solar cells and scribing of thin film solar cells). In addition, laser dicing is becoming the technology of choice to separate silicon IC and sapphire LED wafers into individual dies after device fabrication.

A conventional laser dicing process via materials ablation yields a nominal kerf of 15-50 microns. The kerf loss is negligible in an alternative method of laser dicing. In the so-called Stealth Dicing process, a high intensity laser beam illuminates on front or back sides of the substrates, and focuses inside the substrate materials. The substrate materials is transparent to the laser irradiation of the basic frequency, but can be modified by a multi-photon absorption process at the laser converging point. The extreme temperature at the laser focal point damages the local area inside the substrates, albeit no material is released from the substrate surfaces. After completion of a laser scan on a wafer along the scribe lines, the wafer can be bonded to a supporting tape. When the supporting tape is stretched, dies can be separated along the scribe lines with a near-zero kerf loss. The Stealth Dicing process is already adopted for sapphire substrates in LED fabrication, and is being developed for silicon substrates as well.

Some other laser-based processes in electronics device fabrication involve an anneal (sub-melt) or melt of materials such as silicon. Existing applications include laser anneal for dopant activation in advanced transistor fabrications on silicon wafers in IC fabrication, and melt/recrystallization of an amorphous silicon film on glass substrates in high-resolution flat panel display backplane production. Furthermore, a laser irradiation can selectively melt a bonding layer and detach thin films/materials from the substrates, in a so called laser lift-off process. Existing applications include laser lift-off of LED dies from substrates (e.g. sapphire or silicon), and release of flexible displays from temporary carriers. In a laser lift-off process, a laser illuminates either from back side through the substrate or from the front side through the film stack. A thin interface layer between the film stack and the substrate absorbs the laser irradiation effectively. With a proper laser fluence, the laser irradiation can selectively melt the thin interface layer, en route to a detachment of the film stack from the substrate.

For example, a pulsed ultraviolet laser can be adopted in a laser lift-off process to release LED devices from a sapphire substrate. In a representative LED fabrication flow, a multi-layer film stack including a buffer layer is first deposited on the substrate in an MOCVD process. The composition of the buffer layer is optimized for absorption at the laser wavelength. Another material (e.g. copper) can be then bonded to the top of the film stack. In a subsequent laser lift-off process, a uniform laser beam illuminates from the backside of the substrate, on multiple dies at the same time, and separates the film stack from the substrate by melting the buffer layer. In order to stitch up the laser illumination area on the wafer, it is a common practice to construct a square or rectangular laser beam through a set of optics. A production-worthy laser lift-off process requires a precise control of film composition and uniformity, as well as a consistent laser illumination intensity and uniformity.

### SUMMARY OF THE INVENTION

The present invention relates to methods of fabricating thin electronics and optoelectronics devices, including semiconductor ICs, flat panel displays, and light emitting diodes (LEDs). In a proposed method, electronics and optoelectronics devices are first fabricated on the substrate surface, before the back of substrate is peeled off by a laser irradiation on the substrate sidewall. A wide range of final substrate thickness can be achieved. The cost of the novel substrate thinning process can be very low, and can be relatively independent to the final substrate thickness.

This invention is further directed to methods of separating a substrate into multiple pieces of reduced thickness with a laser irradiation on the substrate sidewall. In one embodiment, the method includes a laser anneal of the materials, accompanied by mechanical forces from front and back surfaces of the substrates to pull apart the materials. In yet another embodiment, the method consists of a multi-step process with sequential laser ablation and laser anneal/melt processes.

### BRIEF DESCRIPTIONS OF THE DRAWINGS

Embodiments are illustrated in the following detailed description and are not limited in the following figures.

FIG. 1 illustrates a perspective view of a substrate subject to a laser irradiation on its side wall.

FIG. 2A/2B illustrates a cross section in a diagrammatic view of an apparatus for substrate separation/thinning, with a substrate passing through a gap between two substrate chucks and exposed to a laser irradiation on its side wall. The two chucks have an increasing gap in between at direction of substrate exiting the apparatus.

FIG. 3 illustrates a perspective view of an apparatus for substrate materials separation/thinning, comprising an assembly of two substrate chucks facing each other, a substrate passing through a gap in between the two substrate chucks, and a laser irradiation for separation of the substrate from the sidewall. The substrate chucks have a curved surface design past the location of laser irradiation. Two resulting areas of the substrate after the laser irradiation can be separated and spread out.

### DETAILED DESCRIPTION OF THE PREFERRED EMBODIMENTS

The following description in combination with the figures is provided to assist in understanding the teachings disclosed herein. The description focuses on specific implementations, embodiments and advantages of the teachings, and should not be interpreted as a limitation on the scope or applicability of the teachings.

The first set of embodiments of the present invention are directed to methods of fabricating thin electronics and optoelectronics devices. The methods relate to a novel substrate thinning process after device fabrication. Different from existing substrate thinning technologies (e.g. materials polish, chemical etch), the proposed substrate thinning process comprises a laser irradiation on the substrate side wall. A layer of substrate can be peeled off in a materials separation process.

The present invention is suitable to various substrate materials, and is applicable to fabrication of various devices. In one embodiment of the present invention, the method is applicable to a reduction in glass substrate thickness for fabrication of thin displays. In the preferred method, displays panels can be first fabricated on regular thickness glass substrates, followed by the proposed substrate thinning process with a laser irradiation on the substrate sidewall. With this approach, the existing display industry manufacturing infrastructure can be adopted as-is without issues of thin substrate handling. In addition, various final glass substrate thickness can be prepared for different target applications. It is conceivable to yield displays with a final glass substrate thickness of 100-200 microns or less, with applications in next generation smart phones/tablets and emerging gadgets with curved and/or flexible surfaces.

As described above, substrate thinning is usually carried out after integrated circuit (IC) fabrication on silicon wafers and light emitting diode (LED) fabrication on sapphire wafers. There are some significant differences between the methods proposed in the present invention and existing wafer thinning processes currently adopted in semiconductor IC and LED fabrications.

First of all, there can be a difference in the preferred manufacturing flows between the proposed display glass thinning process and the existing substrate thinning process in semiconductor IC and LED fabrications. In IC fabrication, round silicon wafers are up to 300 mm (or 450 mm in the future) in diameter, while final dies are in square/rectangular shapes and a few millimeters to a few centimeters in each dimension. In LED fabrication, the sapphire substrates are 50 to 200 mm in diameter, and final dies are less than 1 mm in each dimension. With consideration of original substrate and final die sizes, it is more productive to polish round silicon or sapphire wafers than to grind small individual dies. Therefore it is a standard practice in semiconductor IC and LED device fabrication to thin down silicon or sapphire wafers prior to dicing the wafers into individual dies. In comparison, the preferred fabrication flow can be different for the display glass substrate thinning process proposed in this invention. Full-size glass substrates are rectangular and meters in each dimension, while individual display panels are a few inches in size for smart phones/tablets and tens of inches for televisions. As a result, instead of thinning down full-size substrates, it can be preferred to first cut full-size glass substrates into small size panels after display fabrication is completed, and to thin down individual display panels afterward.

Different from the existing silicon and sapphire wafer polishing processes in semiconductor IC and LED fabrication, there is no production worthy manufacturing technology currently available to reduce rectangular glass thickness after display device fabrication. While regular glasses can be etched in chemical solutions, the etch solutions need to be carefully tailored to handle specific compositions of display glass substrates. A non-uniform surface erosion in chemical etch can also result in a considerable increase in surface roughness en route to a drop in light transmission, not desirable in liquid-crystal displays (LCD). An alternative method is to reduce glass substrate thickness with a mechanical polish process. Proper polish pads and slurry materials need to be developed for specific compositions of the glass substrates in the flat panel display industry, and a grinding/polish process often needs to be followed by a stress-relief step. Furthermore, the rectangular shape of glass substrates can post challenges in grinding/polishing tool design and process control. It is different from existing Si and sapphire wafer grinding/polishing, in which the round shape of the wafers is compatible with a circular motion of the substrates in the grinding process.

In comparison to regular chemical etch and/or mechanical polish processes, the present invention proposes a unique solution for glass substrate thinning after display device fabrication. A laser irradiation on the sidewall can slice an amorphous glass substrate to target thickness. A suitable laser wavelength can be selected to match the absorption spectrum of various silicate based display glasses, as the predominate adsorption peaks do not vary much with small variations in the glass substrate composition. A line-shaped laser beam can be produced to handle the rectangular shape substrates. Under process conditions as claimed in some embodiments of the present invention, the substrate separation process via a laser irradiation on the sidewall can yield smooth and stress free surfaces, with a good optical transmission for target display applications. With a proper hardware setup described below, display devices fabricated on the substrate front side can also be protected in the proposed substrate thinning process.

The substrate thinning process proposed in the present invention can also have a very low manufacturing cost, suitable for the intended applications in display industry. Per unit area, the average sales price (ASP) for flat panel displays is significantly lower than that of the semiconductor IC devices, by as much as two to three orders of magnitude. As a result, the cost of existing substrate grinding/polishing processes, while not predominant in the total production cost of silicon ICs, can be prohibitive in cost-conscious display fabrications. In comparison, a substrate thinning process with a laser irradiation on materials sidewall as claimed in the present invention can have a significantly lower manufacturing cost. The process cost of the proposed substrate thinning methods can also be nearly independent to the required materials removal thickness. It is advantageous to a conventional substrate thinning process with materials removal from backside, either by a chemical etch or a mechanical/chemical polish, which cost increases proportionally to the required materials removal thickness. Overall, the novel substrate thinning methods can reduce glass thickness after display fabrications on the front side of the substrate, and meet the stringent cost requirements in display industry.

In some other embodiments of the present invention, the proposed process of substrate thinning with a laser irradiation after device fabrication is also applicable to silicon and sapphire substrates. For example, it can serve as a replacement technology for silicon substrate thinning in semiconductor IC industry, as well as sapphire substrate thinning in LED production. As discussed above, a silicon IC wafer is often thinned down before dicing to yield a lower profile in IC packaging and/or to enable a die stacking for additional functionalities. In LED fabrication, as a thick starting sapphire wafer is adopted to mitigate a substrate bow in the high temperature MOCVD process, it is desirable to reduce the sapphire substrate thickness after device fabrication for a better light emission in LED operation. Grinding/polishing is the current baseline technology for silicon and sapphire substrate thinning. In comparison, the methods proposed in the present invention for substrate thinning can provide a good protection of fabricated devices, and can offer a significantly lower production cost, which is also independent to materials removal thickness.

In a preferred method of the present invention, an adjustable length laser beam can be constructed (e.g. via a telescope optics design) to accommodate the round shape of silicon and sapphire wafers. Separation/thinning of a silicon or sapphire wafer can start from a single point of laser irradiation on the sidewall. In a continuous wafer slicing/substrate thinning process, the length of the laser beam can be expanded up to wafer diameter and then reduced back to a single point. In an alternative approach, a laser beam can scan across the substrate sidewall, in parallel to substrate surfaces. In this manner, a continuous separation of silicon or sapphire wafers can be accomplished by increasing the length of the laser scan up to wafer diameter and then reducing back to a single point.

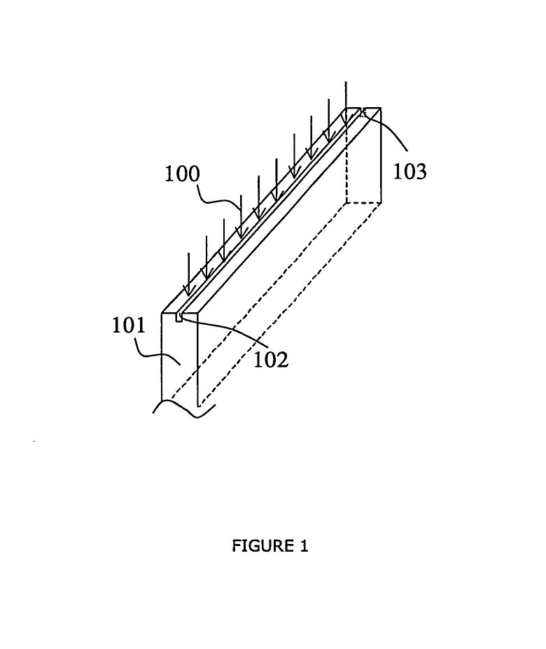

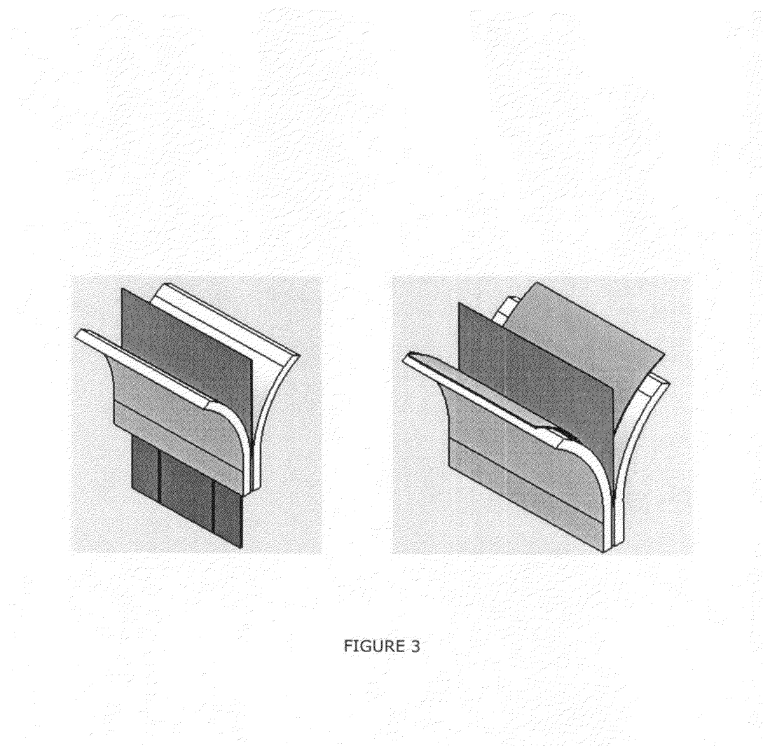

FIGS. 1 to 3 illustrate hardware configurations of the proposed substrate thinning process after device fabrication. As shown in FIG. 1, a focused laser beam 100 can cut a very narrow groove on the side wall of a substrate 101. The length of the laser beam 100 can exceed the dimension of the substrate from Points 102 to 103. The laser beam can take on different shapes, such as a short line, an elliptical spot or a circular spot. In the scenarios that the length of the laser beam is shorter than the dimension of the substrate, a laser irradiation across the substrate sidewall (from Points 102 to 103) can be accomplished by scanning the laser beam or moving the substrate, in a general direction parallel to substrate surfaces.

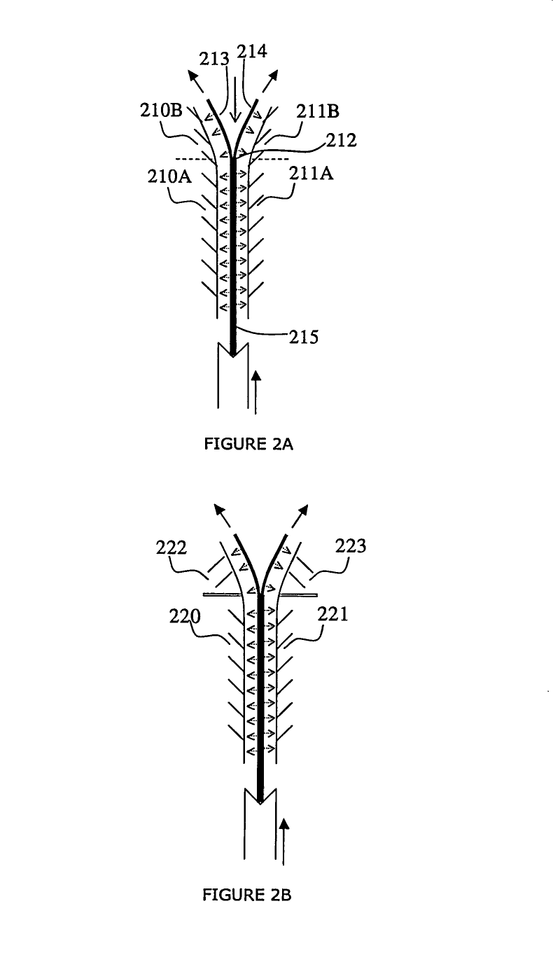

As shown in FIGS. 2A/2B and 3, a substrate can pass through a gap between two substrate chucks and be exposed to a laser irradiation on the substrate side wall. In the proposed substrate thinning process, the focal line of the laser beam can be aligned in parallel to the substrate surfaces, at a distance from the substrate front surface corresponding to the target final substrate thickness. The materials separation process is initiated from the substrate side wall. For square-shaped substrates, a laser line beam of a length exceeding the substrate dimension can be adopted. For round-shaped wafers, the laser irradiation and substrate separation can start from a single point on the wafer sidewall instead.

It is conceivable to have the laser focal plane fixed, and move the substrate through the gap between two substrate chucks toward the focal point of the laser irradiation. In this configuration, the laser irradiation can separate the substrate from sidewall into two pieces in a continuous manner.

The pair of substrate chucks can be a critical module in the materials separation/thinning apparatus. Substrates such as wafers or large sheets of glass can be held in compliance to substrate chucks in different methods: by a pressure delta between two sides of the substrates, by an electrostatic force, etc. Some substrate chucks are in a direct physical contact with the substrates. Some other substrate chucks are in a close proximity to but not in a direct physical contact with the substrates. These non-contact substrate chucks often adopt a fluid-mechanical design and operate like a return spring. The stiffness of the chuck “spring”, as well as the working distance between the substrates and the chuck can be adjustable. Substrates can also be transported across the surface of stationary non-contact fluid-mechanical chucks. Non-contact chucks have been adopted in glass substrate automation for display and thin film solar panel productions, including coating, patterning/scribing, and optical inspection/metrology processes.

In a preferred configuration claimed in the present invention, a materials separation/substrate thinning apparatus comprises of two stationary, non-contact substrate chucks. The two non-contact substrate chucks are mirror image in design. They are placed facing each other in one assembly, with the substrates passing through the gap in between. Non-contact chucks are adopted to protect devices fabricated on the substrate surfaces prior to the materials separation/substrate thinning process. Some surface topography of the substrates and pre-fabricated devices can be accommodated as well. In addition, the two substrate chucks can function as two return springs in tandem to center the substrate in between, regardless of some substrate-to-substrate and with-in substrate thickness variations.

As shown in FIG. 2A, the assembly of two opposite-facing substrate chucks can consist of two portions. The first part of substrate chucks 210A and 211A can be in a general alignment parallel to each other. When a substrate 215 passes through the gap between such portion of the substrate chucks, the substrate sidewall can be centered between the two substrate chucks, and can be aligned to the laser irradiation in the proposed substrate separation process. Past the location of substrate separation 212 in the direction of substrate exiting the apparatus, the second part of two substrate chucks 210B and 211B can have the gap in between gradually increase, and the two resulting substrate areas 213 and 214 can stay compliant to the curved chuck surfaces and get spread out. In a similar configuration, the first portion and second portion of each substrate chuck can be designed as two units adjacent to each other as shown in FIG. 2B (220 and 222, 221 and 223). The second set of substrate chucks 222 and 223 can be operated independently from the first pair of substrate chucks 220 and 221. The two configurations illustrated in FIGS. 2A and 2B share the same concept of spreading out the two resulting areas of the substrate after slicing. Such configurations provide a critical clearance for the laser irradiation to the location of materials separation.

As shown in FIGS. 2A and 2B, the second part of two substrate chucks 210B/211B and 222/223 can adopt a curved chuck surface design. A curved chuck surface design takes advantage of the flexible nature of thin substrates (after laser separation) in the intended applications of the proposed materials separation process. As described above, the nominal substrate thickness in crystalline silicon solar cells is already below 200 microns, and is expected to be further reduced in a continuous effort to lower substrate cost and overall solar cell production cost. In display industry, Gen 5 glass substrate thickness is already ˜300 microns, and a further reduction in display glass thickness is desirable for next generation consumer electronics. Silicon wafers of <200 micron thickness and glass substrates of <300 micron thickness are flexible, and can stay compliant to a curved substrate chuck. Even though some materials such as silicon can be fragile, with a proper surface curvature and a uniform chucking force, the bending force can be well below the materials fracture threshold.

Another set of embodiments in the present invention address preferred methods of materials separation via laser irradiation on substrate sidewall, comprising a novel laser anneal/melt process, which is different from a conventional laser ablation process. At elevated temperatures close to the materials melting points, mechanical strength of solid materials can be reduced significantly. In the hardware configurations proposed in the present invention and shown in FIGS. 2A/2B and 3, a substrate can be separated with the curved chucks pulling from both sides of the substrate. As a result, substrate separation can be accomplished in a mere laser anneal process, versus a conventional laser ablation process.

A materials separation process via laser anneal has several significant advantages over a laser ablation process. First of all, a materials separation/substrate thinning process by laser anneal can be more productive. A laser anneal process can be carried out close to the materials melting point (e.g. 1,412 C for silicon). In comparison, laser ablation takes place significantly above materials evaporation temperature. For instance, the local substrate temperature in a silicon laser ablation process can well exceed 10,000 degrees. As a result, with the same input laser power, a laser anneal tool will be much more productive than a laser ablation system.

With a transient substrate temperature well above materials melting/evaporation points, a laser ablation process often yields “galvanized” as-cut surfaces, which may not be directly compatible with some follow-up device fabrication processes, e.g. backside metalization in solar cell fabrication. In comparison, the present invention proposes a materials separation process via laser anneal. A perfect materials crystal structure (e.g. a single crystal silicon) can be maintained or restored in a laser anneal process, at a temperature close to the materials melting point. For example, a laser spike anneal process has been adopted in advanced IC fabrication to annihilate silicon crystal damages created by high-energy ion implant. As a result, the methods of materials separation via laser anneal as proposed in the present invention can yield high quality surfaces, which can be directly compatible with follow-up processes in many potential applications.

Finally, a method of materials separation by a laser anneal process as proposed in this invention is entitled to a near zero kerf loss and minimal debris formation. In comparison, a conventional laser ablation process carries a nominal kerf loss (e.g. tens of microns in a laser dicing of silicon wafers in IC fabrication), and is accompanied by a considerable debris formation. A negligible kerf loss in the materials separation process proposed in this invention can minimize final materials cost. In addition, a nearly zero debris formation can not only protect fabricated devices on the substrate surfaces, but also reduce contaminations of process equipments, thus improve tool uptime and lower maintenance cost.

It is worthy comparing the novel materials separation process via laser anneal as proposed in this invention with the existing industrial applications of laser anneal. As described in the Background section, a laser spike anneal of silicon (to sub-melt temperature) can be implemented for dopant activation in fabrication of advanced transistors, and a laser melt/recrystalization of an amorphous silicon film deposited on glass substrates is in production of high-resolution flat panel display backplanes. In addition, a laser lift-off technology is adopted in LED and flexible electronics fabrications. The laser lift-off process is designed for materials separation in a heterogeneous system. The process takes advantage of a contrast in optical transmission and absorption between different materials. The substrate or the film stack is transparent, while the interface layer is opaque at the laser wavelength. A laser beam can thus irradiate on the substrate back or front surface, pass through the substrate or the film stack, and melt an interface layer of less than a few micron thick, without any optical focus of the laser beam.

Separation of a homogeneous substrate material is a very different scenario. It is difficult to anneal inside a substrate with a laser irradiation on substrate front or back surfaces. For a laser annealing inside the materials in such configuration, the materials need to be transparent in the laser wavelength, and a proper optical system is necessary to focus the laser irradiation at the desirable depth inside the materials. Depth of focus (DoF) can easily exceed tens of microns, and the process can be hindered by roughness, particles and device structures on the surface. With a laser irradiation on the substrate front or back surface, it can also be challenging to simultaneously apply forces from both front and back surfaces to separate the materials.

In the methods illustrated in the present invention, a laser beam irradiates on a substrate sidewall. The focal width can be a few microns or less. In the preferred method, the materials are opaque at the selected laser wavelength. The laser adsorption can be highly localized on materials sidewall surface, for an efficient heating/anneal of the materials. The laser illumination heats up the materials close to the melting point, and materials can be separated with chucking forces applied from front and back surfaces of the substrate. In a proposed materials separation tool configuration shown in FIGS. 2A/2B and 3, two substrate chucks are assembled facing each other with a gap in between, with a substrate passing through. The substrate chuck design can have curved surfaces past the location of laser irradiation. In the proposed materials separation process, the maximum temperature for laser anneal is close to the materials melting point. As discussed above, the materials mechanical strength can be significantly reduced, and the materials can be separated with proper forces applied from front and back sides of the substrate.

In production equipment and process designs, the optimal anneal temperature is determined by the quality of materials separation as well as equipment throughput/cost. As a result, although materials mechanical strength can be significantly reduced below the melting point, the maximum temperature in the proposed laser anneal process for substrate separation may reach or slightly exceed the materials melting point.

Some other embodiments of the present invention cover some details in the preferred methods. It is conceivable to adopt a pulsed laser in the proposed methods for materials separation. Not only a pulsed laser can deliver high energy density to the workpiece, a laser with a pulse duration of nanoseconds or shorter can even heat up the materials at a time scale less than that of thermal diffusion/dissipation. As a result, with the same averaged power, a short pulsed laser can anneal the materials to a maximum temperature significantly higher than a continuous wave (CW) or long pulse laser. Besides laser wavelength and pulse duration, laser pulse energy and repetition rate are also important parameters in determining the maximum anneal temperature.

In another set of embodiments in the present invention, a substrate is separated by a laser irradiation from its sidewall, with a combination of laser ablation and laser anneal processes. In the proposed method, materials separation can be first initiated by laser ablation, which cuts a narrow groove at the sidewall of the substrate leading edge. With the substrate leading edge passes through the laser focal point, the small portion of the substrate at two sides of the laser ablation groove can stay compliant to the two curved substrate chucks, respectively. The subsequent materials separation process can be carried out in a laser anneal regime. As discussed above, a focused laser beam can heat the substrate to a temperature close to materials melting point. Materials mechanical strength can be significantly reduced, and with the hardware configuration illustrated above, the substrate can be separated by chucking forces applied on both sides of the substrate.

Laser ablation and laser anneal have significantly different operation regimes. The proposed laser anneal process is performed at a substrate maximum temperature close to the materials melting point. By contrast, a laser ablation process typically takes place at a substrate maximum temperature thousands or tens of thousands of degrees higher than the materials melting point. Compared with a laser anneal process, laser ablation can require a significantly higher energy density on the workpiece. The laser ablation and laser anneal can be carried out sequentially in different tools. In some methods proposed in the present invention, they can be also conducted in one single equipment. One approach is to modulate laser operating conditions, including wavelength, pulse duration and pulse energy. For instance, a higher modulation frequency in diode pumped solid state (DPSS) lasers can lead to a decrease of pulse energy, along with a slight increase in pulse duration. Through the same set of optics, a decrease of laser pulse energy and an increase in laser pulse duration can translate to a lower laser fluence and a lower energy density on the workpiece, en route to a lower substrate temperature. The process can be thus switched from a laser ablation to a laser anneal regime. In another approach, the laser operating conditions can be fixed, and the laser beam profile (e.g. length, width) on the workpiece can be adjusted through optics control. For example, the optics system can incorporate a telescope design for a modulation in laser beam length. With the same laser pulse energy and pulse duration, an increase of laser beam length can reduce energy density on the workpiece, and switch the process from a laser ablation initiation step to a subsequent laser anneal step for materials separation.

What is claimed is:

1. A method of fabricating devices on a substrate, comprising:
forming devices on at least one substrate surface;
reducing the thickness of said substrate by laser irradiating a substrate sidewall, wherein the surface area of the substrate after fabricating the devices is substantially the same surface area of the substrate prior to reducing the thickness of said substrate.

2. A method according to claim 1, wherein said substrate comprises silicon.

3. A method according to claim 1, wherein said substrate comprises glass, and the composition of the glass comprises of >50% silicon oxide.

4. A method according to claim 1, wherein said substrate comprises sapphire.

5. A method of processing a substrate, comprising:
irradiating a laser beam onto at least a section of a substrate sidewall, wherein the laser irradiation heats the materials of said substrate to a maximum temperature of 75-125% of the materials melting point;
and separating the substrate into two pieces, wherein each of the two pieces of the substrate comprises substantially the same surface area of the substrate prior to the separation.

6. The method according to claim 5, wherein the substrate thickness before separation is less than 500 microns.

7. The method according to claim 5, wherein the substrate comprises silicon.

8. The method according to claim 5, wherein said substrate comprises glass, and the composition of the glass comprises of >50% silicon oxide.

9. The method according to claim 8, wherein the maximum substrate temperature in said laser heating is between 500 C and 1,100 C.

10. The method according to claim 6, wherein said substrate comprises sapphire.

11. A method of processing a substrate, comprising:
cutting a groove on at least a section of a substrate sidewall;
heating the substrate sidewall with a laser beam, wherein the laser beam heats the materials of said substrate to a maximum temperature of 75-125% of the materials melting point;
and separating the substrate into two pieces, wherein each of the two pieces of the substrate comprises substantially the same surface area of the substrate prior to the separation.

12. A method according to claim 11, wherein cutting the groove on the substrate sidewall comprises materials ablation by a laser irradiation, wherein the laser irradiation in the materials ablation process heats the materials of said substrate to a maximum temperature exceeding 200% of the materials melting point.

13. A method according to claim 11, further comprising change in laser operating conditions between laser ablation in substrate cutting and laser heating in substrate separation processes.

14. A method according to claim 11, further comprising changing the optics setting between laser ablation in substrate cutting and laser heating in substrate separation processes.

15. A method of processing a substrate, comprising:
positioning the substrate between two substrate chucks, wherein a first substrate chuck is in close proximity to a front surface of the substrate, and a second substrate chuck is in close proximity to a back surface of the substrate;
irradiating a laser beam onto a sidewall of the substrate; and
separating the substrate into two pieces, wherein each of the two pieces of the substrate comprises substantially the same surface area of the substrate prior to the separation.

16. A method according to claim 15, wherein the first substrate chuck is in contact with the front surface of the substrate, and the second substrate chuck is in contact with the back surface of the substrate.

17. A method according to claim 15, wherein said laser is pulsed in operation, and the laser pulse duration is less than 1 microsecond.

18. A method according to claim 17, wherein the laser pulse duration is less than 10 nanoseconds.

19. A method according to claim 15, wherein the profile of laser irradiation on the substrate is adjustable.
